(19) United States
(12) Patent Application Publication
(10) Pub. No.: US 2025/0323213 A1
(43) Pub. Date: Oct. 16, 2025

(54) SEMICONDUCTOR PACKAGE

(71) Applicant: Samsung Electronics Co., Ltd., Suwon-si (KR)

(72) Inventors: Minjung KIM, Suwon-si (KR); Ilho KIM, Suwon-si (KR)

(73) Assignee: Samsung Electronics Co., Ltd., Suwon-si (KR)

(21) Appl. No.: 19/002,152

(22) Filed: Dec. 26, 2024

(30) Foreign Application Priority Data
Apr. 16, 2024 (KR) 10-2024-0050537

(51) Int. Cl. H01L 25/065; H01L 23/00; H01L 23/31

(52) U.S. Cl. CPC H01L 25/0652; H01L 23/3135; H01L 24/08; H01L 24/32; H01L 24/48; H01L 24/73; H01L 25/0657; H01L 2224/08111; H01L 2224/32225; H01L 2224/48148; H01L 2224/48227; H01L 2224/48464; H01L 2224/48992; H01L 2224/73265; H01L 2225/06506; H01L 2225/0651; H01L 2225/06562; H01L 2924/35

(57) ABSTRACT

A semiconductor package including a first semiconductor chip, which includes a first semiconductor board, a bonding pad on the first semiconductor board, and a protection layer covering an upper surface of the first semiconductor board and including a recessed region exposing at least a portion of an upper surface of the bonding pad therethrough, a second semiconductor chip including a second semiconductor board in direct contact with the protection layer, and a wire electrically connecting the first semiconductor chip and the second semiconductor chip and connected to the bonding pad may be provided.

### CROSS-REFERENCE TO RELATED APPLICATION(S)

This application claims the benefit of Korean Patent Application No. 10-2024-0050537, filed on Apr. 16, 2024, in the Korean Intellectual Property Office, the disclosure of which is incorporated herein by reference.

### BACKGROUND

### 1. Field

Example embodiments relate to semiconductor packages.

### 2. Description of the Related Art

In accordance with the rapid development of the electronics industry and user demands, electronic devices are becoming smaller, higher-capacity and multi-functional. In order to implement these requirements, a semiconductor package containing multiple semiconductor chips is required. Specifically, multiple semiconductor chips are stacked using a die attach film (DAF) between chips, but due to the thickness of the DAF itself, such a structure is disadvantageous for miniaturization. Further, the DAF has a higher coefficient of thermal expansion than the semiconductor chips, so there is a possibility that the semiconductor chips may peel off or may be separated due to the expansion of the DAF.

### SUMMARY

An example embodiment of the present disclosure provides a semiconductor package by which thermal characteristics and package strength are improved without applying a die attach film (DAF) between semiconductor chips (e.g., DAF free), and the wire bonding process may be performed stably.

The technical effects and advantages to be achieved by the present disclosure are not limited to the technical effects and advantages described above, and other technical effects and advantages may be inferred from the following example embodiments by those skilled in the art.

According to an example embodiment, a semiconductor package may include a first semiconductor chip including a first semiconductor board, a bonding pad on the first semiconductor board, and a protection layer covering an upper surface of the first semiconductor board, the protection layer including a recessed portion, the recessed portion exposing at least a portion of an upper surface of the bonding pad therethrough, a second semiconductor chip including a second semiconductor board, the second semiconductor board being in direct contact with the protection layer, and a wire electrically connecting the first semiconductor chip and the second semiconductor chip, is the wire being connected to the bonding pad.

According to an example embodiment, a semiconductor package may include a first semiconductor chip including a first semiconductor board, a bonding pad on the first semiconductor board, and a protection layer covering an upper surface of the first semiconductor board, the protection layer including a recessed portion, the recessed portion exposing at least a portion of an upper surface of the bonding pad therethrough, a second semiconductor chip including a second semiconductor board, the second semiconductor board being in direct contact with the protection layer, and a wire electrically connecting the first semiconductor chip and the second semiconductor chip, is the wire being connected to the bonding pad, wherein the bonding pad includes a first pad side wall overlapping the protection layer when viewed in a first direction perpendicular to the upper surface of the bonding pad, and a second pad side wall being on an opposite side of the first pad side wall based on a width direction of the first semiconductor chip, the second pad side wall not overlapping the protection layer when viewed in the first direction.

According to an example embodiment, a semiconductor package may include a package board, a first semiconductor chip on the package board, the first semiconductor chip including a first semiconductor board, a bonding pad on the first semiconductor board, and a protection layer covering an upper surface of the first semiconductor board, the protection layer including a recessed portion, the recessed portion exposing at least a portion of an upper surface of the bonding pad therethrough, an adhesive layer between the package board and the first semiconductor chip, a second semiconductor chip including a second semiconductor board, is the second semiconductor chip being in direct contact with the protection layer, a wire electrically connecting the first semiconductor chip and the second semiconductor chip, is the wire being connected with the bonding pad, a wire ball on the bonding pad, the wire ball connecting the wire and the bonding pad, and a molding film covering the recessed portion, the first semiconductor chip, and the second semiconductor chip, wherein the first semiconductor chip includes a first side wall not overlapping the second semiconductor chip when viewed in a first direction perpendicular to the upper surface of the bonding pad, and a second side wall being on an opposite side of the first side wall based on a width direction of the first semiconductor chip, the second side wall overlapping the second semiconductor chip when viewed in the first direction, wherein the bonding pad includes a first part where the upper surface of the bonding pad overlaps the protection layer when viewed in the first direction, and a second part where the upper surface of the bonding pad is exposed through the protection layer through the opening when viewed in the first direction, and wherein the first part is closer to the first side wall than the second part based on the width direction of the first semiconductor chip.

The technical effects and advantage of the present disclosure are not limited to the technical effects and advantage described above, and other technical effects and advantage not mentioned herein will be clearly understood by those skilled in the art from the following description.

According to some example embodiments, it is possible to provide a semiconductor package by which thermal characteristics and package strength are improved without applying the DAF between semiconductor chips (DAF free), and wire bonding process is performed more stably.

Additional features and advantages of the inventive concepts will be set forth in the description which follows, and in part will be apparent from the description, or may be learned by practice of the inventive concepts. The effects and other advantages of the inventive concepts will be realized and attained by the structure particularly pointed out in the written description and claims hereof as well as the appended drawings.

### BRIEF DESCRIPTION OF THE DRAWINGS

These and/or other aspects, features, and advantages of the inventive concepts will become apparent and more readily appreciated from the following description of some example embodiments, taken in conjunction with the accompanying drawings of which:

FIG. 1 is a plan view illustrating a semiconductor package according to a first example embodiment;

FIG. 2 is an enlarged plan view of portion A of FIG. 1;

FIG. 3 is a plan view illustrating a semiconductor package according to a second example embodiment;

FIG. 4 is an enlarged plan view of portion A′ of FIG. 3;

FIG. 5 is a plan view illustrating a semiconductor package according to a third example embodiment;

FIG. 6 is an enlarged plan view of portion A″ of FIG. 5;

FIG. 7 is a plan view illustrating a semiconductor package according to a fourth example embodiment;

FIG. 8 is a plan view illustrating a semiconductor package according to a fifth example embodiment;

FIG. 9 is a plan view illustrating a semiconductor package according to a sixth example embodiment; and

FIGS. 10 to 26 are cross-sectional views illustrating a method of manufacturing a semiconductor package operation by operation according to an example embodiment.

### DETAILED DESCRIPTION

Prior to the detailed description of the present disclosure, terms or words used in the specification and claims may not be construed as limited to their common or dictionary meanings. Further, the terms or words should be interpreted with meaning(s) and concept(s) consistent with the technical ideas of the present disclosure based on the principle that the inventor may appropriately define the concept(s) of terms in order to explain his or her inventive concepts as appropriate. The example embodiments described in this specification and the configurations shown in the drawings are merely some example embodiments of the present disclosure, and do not necessarily represent the entire technical ideas of the present disclosure. Accordingly, at the time of filing the present disclosure, there may be various equivalents and modifications that can replace them.

The same reference numeral or sign shown in each drawing attached to the specification may represent parts or components that perform substantially the same function. For convenience of description and understanding, different example embodiments may be described using the same reference numerals or symbols. In other words, even if a component or an element having the same reference numeral is shown in multiple drawings, the multiple drawings may not all represent a single example embodiment.

In the present disclosure, when an element is described as being “on” or “adjacent to” another element, the element may be understood as being in direct contact with or connected to the another element, but it also may be understood that another element exist between the two. Further, in the present disclosure, when an element is described as being “directly on,” “adjacent to” or “in contact with” another element, it may be understood that there is no other element between the two. Other similar expressions describing the positional relationship between elements can also be interpreted similarly as above.

In the following description, singular expressions include plural expressions unless the context clearly dictates otherwise. It will be understood that, when an element (e.g., a first element) is “(operatively or communicatively) coupled with/to” or “connected to” another element (e.g., a second element), the element may be directly coupled with/to another element, and there may be an intervening element (e.g., a third element) between the element and another element. The terms “have,” “may have,” “include,” and “may include” as used herein indicate the presence of corresponding features (e.g., elements such as numerical values, functions, operations, or parts), and do not preclude the presence of additional features.

Further, in the following description, expressions such as an upper side, top, a lower side, bottom, a side, front and a back side are expressed based on the direction shown in the drawing. If the direction of the object changes, it may be expressed differently.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If desired, each ordinal number may be used interchangeably.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

The drawings illustrated in the present disclosure are merely some example embodiments, and the ratio of the width, the length and the height (or the thickness) of each element are not precisely scaled for detailed descriptions of the example embodiments, and thus the ratio may differ from reality. Further, in the coordinate system illustrated in the drawings, axes may be perpendicular to each other, and a direction that the arrow points may be a + direction, and another direction opposite to the direction indicated by the arrow (rotated by 180 degrees) may be a − direction.

Further, in the following description, “US” indicated in reference numerals refers to an upper surface, “BS” indicated in reference numerals refers to a bottom surface, “SW” indicated in reference numerals refers to a side wall, and “T” indicated in reference numerals refers to surface treatment.

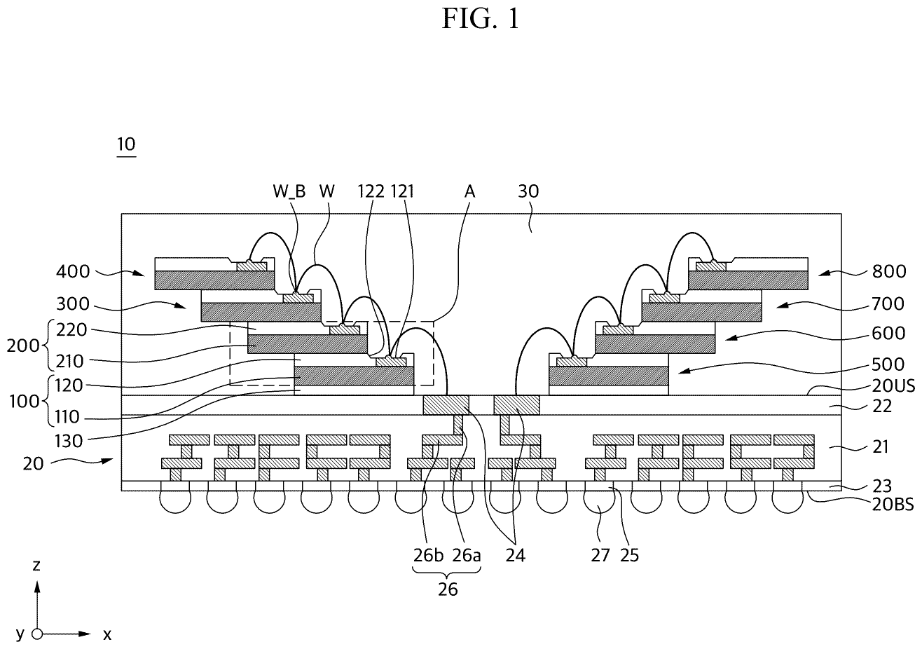

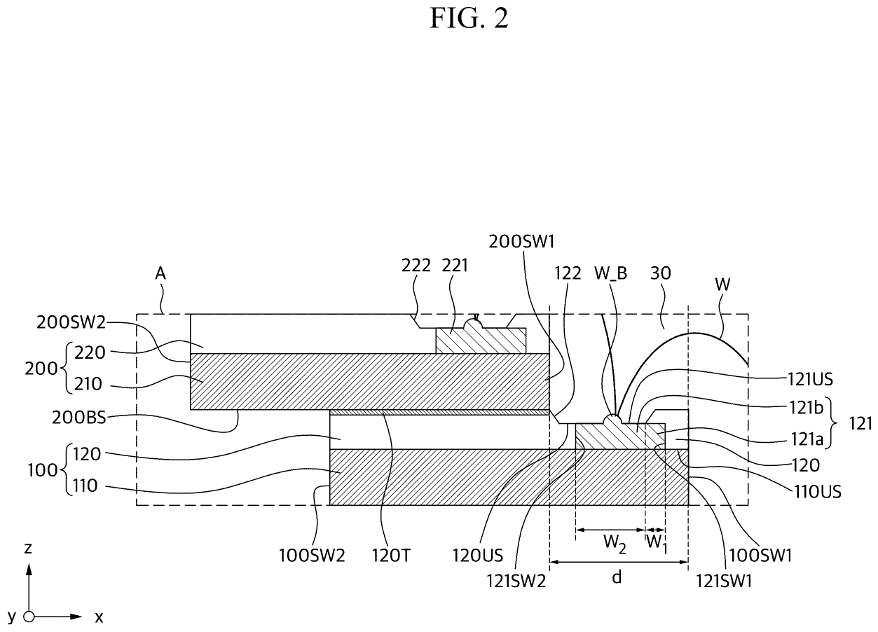

FIG. 1 is a plan view illustrating a semiconductor package 10 according to a first example embodiment. FIG. 2 is an enlarged plan view of portion A of FIG. 1.

The semiconductor package 10 according to the example embodiment may include a plurality of semiconductor chips, which includes a first semiconductor chip 100, a second semiconductor chip 200, a third semiconductor chip 300, a fourth semiconductor chip 400, a fifth semiconductor chip 500, a sixth semiconductor chip 600, a seventh semiconductor chip 700 and an eighth semiconductor chip 800. FIG. 1 illustrates that the semiconductor package 10 includes a total of eight semiconductor chips. Among the eight semiconductor chips, the first semiconductor chip 100, the second semiconductor chip 200, the third semiconductor chip 300, and the fourth semiconductor chip 400 may be stacked to from a first group of four semiconductor chips, and the fifth semiconductor chip 500, the sixth semiconductor chip 600, the seventh semiconductor chip 700 and the eighth semiconductor chip 800 may be stacked to form a second group of four semiconductor chips. However, the number of semiconductor chips included in the semiconductor package 10 is not particularly limited thereto.

Hereinafter, described in detail is the semiconductor 10 including the first semiconductor chip 100 and the second semiconductor chip 200 placed on the first semiconductor chip 100 according to the example embodiment. Descriptions regarding thereto may also be applied to other semiconductor chips included in the semiconductor package 10. For example, descriptions with respect to the first semiconductor chip 100 may be referred to as descriptions about the fifth semiconductor chip 500, and descriptions with respect to the second semiconductor chip 200 may be referred to as descriptions about the third semiconductor chip 300, the fourth semiconductor chip 400, the sixth semiconductor chip 600, the seventh semiconductor chip 700 and the eighth semiconductor chip 800.

The semiconductor package 10 according to the example embodiment may include the first semiconductor chip 100 including a first semiconductor board 110, a bonding pad 121 and a protection layer 120. The bonding pad 121 may be placed on the first semiconductor board 110. The protection layer 120 may include an opening (or alternatively, a recessed portion) 122. The opening 122 refers to a portion of the protection layer 120 where the upper surface thereof is recessed, The opening 122 may cover an upper surface 110US of the first semiconductor board 110 and expose at least a portion of the upper surface 121US of the bonding pad 121 therethrough. In an example embodiment, the opening

122 may be on the upper surface 110US of the first semiconductor board 110 and expose a portion of the upper surface 121US of the bonding pad 121.

The first semiconductor board 110 according to the example embodiment may include silicon (Si). Further, the first semiconductor board 110 may include a compound semiconductor containing one or more selected from the group consisting of indium (In), gallium (Ga), zinc (Zn), silicon (Si), tin (Sn), zirconium (Zr), hafnium (Hf), aluminum (Al) and ytterbium (Yb). Further, the first semiconductor board 110 may have a silicon on an insulator (SOI) structure in an example embodiment. Further, in an example embodiment, the first semiconductor board 110 may have a conductive region containing an impurity-doped well or an impurity-doped structure. Further, in an example embodiment, the first semiconductor board 110 may have a device isolation structure such as a shallow trench isolation (STI) structure. Meanwhile, the first semiconductor board 110 may have a wiring structure formed so that semiconductor devices (not illustrated), which will be described later, can be electrically connected.

The semiconductor devices (not illustrated) may be placed on the first semiconductor board 110 according to the example embodiment. The semiconductor devices may include one or more selected from the group consisting of system large scale integration (LSI), flash memory, DRAM, SRAM, EEPROM, PRAM, MRAM, FeRAM and RRAM. The semiconductor devices may include multiple individual devices of various types. The multiple individual devices are not particularly limited as long as they are used in the art, but the multiple individual devices may include image sensors, active elements, and/or passive elements such as metal-oxide-semiconductor field effect transistors (MOSFETs) such as complementary metal-oxide-semiconductor (CMOS) transistors or a CMOS imaging sensor (CIS). The semiconductor devices may be electrically connected to the first semiconductor board 110, and for this, the semiconductor devices may include conductive wiring or conductive plugs. Further, a plurality of individual devices included in the semiconductor devices may be electrically separated from each other by an insulating film. Meanwhile, the semiconductor devices included in the first semiconductor chip 100 and the second semiconductor chip 200 may be different.

The first semiconductor board 110 according to the example embodiment may include a plurality of wiring structures to be electrically connected to the plurality of individual devices. The plurality of wiring structures may include a metal wiring layer and a via layer. Each of the metal wiring layer and the via layer may include a barrier film for wiring and a metal layer for wiring, respectively. The barrier film for wiring may include one or more selected from the group consisting of titanium (Ti), titanium nitride (TiN), tantalum (Ta) and tantalum nitride (TaN). The metal layer for wiring may include one or more selected from the group consisting of tungsten (W), aluminum (Al), and copper (Cu). Included may be a plurality of metal wiring layers and a plurality of via layers, and the metal wiring layers and the via layers may form a multi-layer structure. For example, the wiring structure may be multi-layered in which two or more metal wiring layers and two or more via layers are alternately stacked.

The bonding pad 121 according to the example embodiment may include a first part 121a where the upper surface 121US of the bonding pad 121 overlaps the protection layer 120 when viewed from the direction perpendicular to the upper surface 121US of the bonding pad 121 (the z-axis direction). Further, the bonding pad 121 may include a second part 121b in which the upper surface 121US of the bonding pad 121 is exposed from the protection layer 120 when viewed from the direction perpendicular to the upper surface 121US of the bonding pad 121 (the z-axis direction). In other words, the bonding pad 121 may include the first part 121a and the second part 121b. Referring to FIG. 2, it may be identified that the bonding pad 121 may be separated into the first part 121a and the second part 121b depending on whether the upper surface 121US of the bonding pad 121 overlaps the protection layer 120 when viewed from the direction perpendicular to the upper surface 121US of the bonding pad 121 (the z-axis direction). Meanwhile, in the present disclosure, “vertical direction” may be the same as the z-axis direction in the drawings. Further, “width direction” may be the same as the x-axis direction in the drawings, and “longitudinal direction” may be the same as the y-axis direction in the drawings.

The protection layer 120 according to the example embodiment may be an insulating layer. The material of protection layer 120 is not particularly limited as long as it includes insulating materials used in the industry. For example, the protection layer 120 may include one or more selected from the group consisting of oxides such as SiOx (x is greater than 0 and less than or equal to 2), nitrides such as silicon nitride (SiN), and photosensitive polyimide (PSPI). The protection layer 120 may be formed as a single-layer or multi-layer structure.

The bonding pad 121 according to the example embodiment may include one or more selected from the group consisting of tungsten (W), aluminum (Al), copper (Cu), titanium (Ti), titanium nitride (TiN), tantalum (Ta), tantalum nitride (TaN), gold (Au) and silver (Ag).

According to the example embodiment, a wire W connected to the bonding pad 121 of the first semiconductor chip 100 may electrically connect the first semiconductor chip 100 to the second semiconductor chip 200. The wire W can electrically connect other semiconductor chips (e.g., the third semiconductor chip 300 and the fourth semiconductor chip 400) with the first semiconductor chip 100 and the second semiconductor chip 200. The wire W may also be connected to the bonding pad included in the second semiconductor chip 200, in addition to the bonding pad 121 of the first semiconductor chip 100, and connect the second semiconductor chip 200 to the fourth semiconductor chip 400. Meanwhile, the wire W may electrically connect each of the semiconductor chips described above to a package board 20 (e.g., an upper part board pad 24 placed on the package board 20).

The first semiconductor chip 100 according to the example embodiment may have a first side wall 100SW1 and a second side wall 100SW2 based one direction. Referring to FIG. 2, the first semiconductor chip 100 may have the first side wall 100SW1 located on one side and the second side wall 100SW2 located on the opposite side based on the width direction (the x-axis direction). Here, the first side wall 100SW1 may not overlap the second semiconductor chip 200 when viewed from a direction perpendicular to the upper surface 121US of the bonding pad 121 (the z-axis direction). Further, the second side wall 100SW2 may be located on the opposite side of the first side wall 100SW1 based on the width direction (the x-axis direction) of the first semiconductor chip 100, and the second side wall 100SW2 may overlap the second semiconductor chip 200 when viewed from the direction perpendicular to the upper surface 121US of the bonding pad 121 (the z-axis direction). Specifically, the first side wall 100SW1 may be one side surface that is located on one side based on the x-axis direction of the first semiconductor chip 100 that is not in contact with (e.g., not under) the second semiconductor chip 200 based on the z-axis direction, and the second side wall 100SW2 is the opposite side surface located on the opposite side based on the x-axis direction of the first semiconductor chip 100 that is contact with (e.g., under) the second semiconductor chip 200 based on the z-axis direction.

According to the example embodiment, based on the width direction (the x-axis direction) of the first semiconductor chip 100, the first part 121a of the bonding pad 121 may be closer to the first side wall 100SW1 of the first semiconductor chip 100 than the second part 121b. In other words, when viewed from the direction perpendicular to the upper surface 121US of the bonding pad 121 (the z-axis direction), the protection layer 120 overlapping the first part 121a may be closer to the first side wall 100 SW1 of the first semiconductor chip 100 than the second side wall 100 SW2 thereof, based on the width direction (the x-axis direction) of the first semiconductor chip 100. With the arrangement, the bonding pad 121 may be mitigated or prevented from being separated from the first semiconductor board 110.

The wire W according to the example embodiment electrically connects the plurality of semiconductor chips to the package board 20, and thus tension may be applied to the wire W depending on the bonding state between each semiconductor chip and the difference in bonded positions of each semiconductor chip. If strong tension is applied to the wire W, the surface of the bonding pad 121 may peel off and be damaged. According to the example embodiment, when viewed from the direction perpendicular to the upper surface 121US of the bonding pad 121 (the z-axis direction), the protection layer 120 overlapping the first part 121a is closer to the first side wall 100SW1 of the first semiconductor chip 100 based on the width direction (the x-axis direction) of the first semiconductor chip 100, and thus the wire W may contact the protection layer 120. Accordingly, because some of the tension is distributed to the protection layer 120, the possibility of damage to the bonding pad 121 may be reduced.

According to the example embodiment, a width W2 of the second part 121b of the bonding pad 121 may be larger than a width W1 of the first part 121a based on the width direction (the x-direction) of the first semiconductor chip. The width W1 of the first part 121a and the width W2 of the second part 121b may be defined based on the width direction (the x-axis direction) of the first semiconductor chip 100. When viewed from the direction perpendicular to the upper surface 121US of the bonding pad 121 (the z-axis direction), by making the width W2 of the second part 121b where the upper surface 121US of the bonding pad 121 is exposed from the protection layer 120 larger than the width W1 of the first part 121a that overlaps the protection layer 120, the wire W may easily contact the bonding pad 121.

The bonding pad 121 according to the example embodiment may have two pad side walls, which are a first pad side wall 121SW1 and a second pad side wall 121SW2, based on one direction. Referring to FIG. 2, the bonding pad 121 may have the first pad side wall 121SW1 located on one side based on the width direction (the x-axis direction) of the first semiconductor chip 100 and the second pad side wall 121SW2 located on the opposite side. Here, the first pad side wall 121SW1 may overlap the protection layer 120 with respect to the upper surface 121US of the bonding pad 121, when viewed from the direction perpendicular to the upper surface 121US of the bonding pad 121 (the z-axis direction). Further, the second pad side wall 121SW2 may be located on the opposite side of the first pad side wall 121SW1 based on the width direction (the x-axis direction) of the first semiconductor chip 100, and the second pad side wall 121SW2 may not overlap the protection layer 120 when viewed in a direction perpendicular to the upper surface 121US of the bonding pad 121 (the z-axis direction). Specifically, the first pad side wall 121SW1 may be one side surface located on one side based on the x-axis direction of the bonding pad 121 that overlaps the protection layer 120 when viewed in the z-axis direction, and the second pad side wall 121SW2 may be the opposite side surface that is located on the opposite side based on the x-axis direction of the bonding pad 121 that does not overlap the protection layer 120.

According to the example embodiment, the first pad side wall 121SW1 may be closer to the first side wall 100SW1 of the first semiconductor chip 100 than the second pad side wall 121SW2 based on the width direction (the x-axis direction) of the first semiconductor chip 100. With the arrangement, may be expected is the same technical effects as can be expected from the first part 121a of the bonding pad 121 being placed closer to the first side wall 100SW1 of the first semiconductor chip 100 than the second part 121b based on the width direction of the first semiconductor chip 100 (the x-axis direction).

Meanwhile, the bonding pad 121 according to the example embodiment may include the first part 121a where the upper surface 121US of the bonding pad 121 overlaps the protection layer 120 when viewed from the direction perpendicular to the upper surface 121US of the bonding pad 121 (the z-axis direction). The first part 121a includes the first pad side wall 121SW1.

Further, the bonding pad 121 according to the example embodiment may include the second part 121b where the upper surface 121US of the bonding pad 121 is exposed from the protection layer 120 through the opening 122 when viewed from the direction perpendicular to the upper surface 121US of the bonding pad 121 (the z-axis direction). The second part 121b includes the second pad side wall 121SW2.

Here, the width W2 of the second part 121b of the bonding pad 121 may be larger than the width W1 of the first part 121a based on the width direction (the x-axis direction) of the first semiconductor chip 100. The wire W may easily contact the bonding pad 121 by making the width W2 of the second part 121b where the upper surface 121US of the bonding pad 121 is exposed from the protection layer 120 larger than the width W1 of the first part 121a overlapping the protection layer 120 when viewed from the direction perpendicular to the upper surface 121US of the bonding pad 121 (the z-axis direction).

The semiconductor package 10 according to an example embodiment may include the second semiconductor chip 200 including a second semiconductor board 210 in direct contact with the protection layer 120 of the first semiconductor chip 100. For example, the upper surface of the protection layer 120 and the bottom surface of the second semiconductor board 210 may be in direct contact with each other while facing each other. In other words, the protection layer 120 of the first semiconductor chip 100 and the second semiconductor board 210 may be in direct contact without a separate intermediate element. Through this, an adhesive layer such as a die attach film (DAF) is not placed between the first semiconductor chip 100 and the second semiconductor chip 200 (DAF free), thereby improving thermal characteristics and package strength.

The protection layer 120 according to the example embodiment may include a surface treatment layer 120T in contact with a bottom surface 200BS of the second semiconductor chip 200. The surface treatment is not particularly limited as long as surface properties are changed by applying physical and/or chemical changes to the surface. For example, the surface treatment layer 120T may have adhesive properties through surface treatment. Further, in an example embodiment, if a thin film is formed between the protection layer 120 and the second semiconductor chip 200 due to the surface treatment, it may satisfy the definition of direct contact between the first semiconductor chip 100 and the second semiconductor chip 200 without a separate intermediate element. For example, the surface treatment layer 120T according to an example embodiment may be formed with plasma or low-wavelength energy rays. For example, the surface treatment layer 120T may be formed by surface treating the protection layer 120 by applying plasma or low-wavelength energy rays. Here, the low-wavelength energy rays may refer to light rays having a wavelength of about 300 nm or less.

The second semiconductor chip 200 according to the example embodiment may not overlap with the opening 122 of the first semiconductor chip 100 when viewed from the direction perpendicular to the upper surface 121US of the bonding pad 121 (the z-axis direction). Meanwhile, the second semiconductor chip 200, like the first semiconductor chip 100 described above, may include the second semiconductor board 210, a bonding pad 221, and a protection layer 220. The above descriptions on the first semiconductor board 110 may be referred to as descriptions for the second semiconductor board 210.

Like the first semiconductor chip 100, the second semiconductor chip 200 according to the example embodiment may have both side walls, which are a third side wall 200SW1 and a fourth side wall 200SW2, based on one direction. Referring to FIG. 2, the second semiconductor chip 200 may have the third side wall 200SW1 located on one side based on the width direction (the x-axis direction) and the fourth side wall 200SW2 located on the opposite side. Meanwhile, the width direction of the first semiconductor chip 100 and the width direction of the second semiconductor chip 200 may be the same (the x-axis direction). Here, the third side wall 200SW1 may overlap the first semiconductor chip 100 when viewed in the direction perpendicular to the upper surface 121US of the bonding pad 121 of the first semiconductor chip 100 (the z-axis direction). Further, the fourth side wall 200SW2 may be located on the opposite side of the third side wall 200SW1 based on the width direction (the x-axis direction) of the first semiconductor chip 100, and the fourth side wall 200SW2 may not overlap the first semiconductor chip 100 when viewed in the direction perpendicular to the upper surface 121US of the bonding pad 121 (the z-axis direction). Specifically, the third side wall 200SW1 may be one side surface that is located on one side based on the x-axis direction of the second semiconductor chip 200 that is in contact with the first semiconductor chip 100 based on the z-axis direction, and the fourth side wall 200SW2 may be the opposite side surface that is located on the opposite side based on the x-axis direction of the second semiconductor chip 200 that is in contact with the first semiconductor chip 100 based on the z-axis direction.

In the semiconductor package 10 according to the example embodiment, a separated distance d between the first side wall 100SW1 of the first semiconductor chip 100 and the third side wall 200SW1 of the second semiconductor chip 200 may be at least 20 μm or greater based on the width direction (the x-axis direction) of the first semiconductor chip 100. In another example embodiment, the separated distance d between the first side wall 100SW1 and the third side wall 200SW1 may be, for example, 100 μm or greater or 200 μm or less based on the width direction (the x-axis direction) of the first semiconductor chip 100. However, separated distance d is not particularly limited.

The first semiconductor chip 100 according to the example embodiment may further include a wire ball W_B connecting the wire W and the bonding pad 121. The wire ball W_B may be separated (spaced apart) from the second semiconductor chip 200 in the width direction (the x-axis direction) of the first semiconductor chip 100. In other words, the second semiconductor chip 200 stacked on the first semiconductor chip 100 may not be in contact with the wire ball W_B.

The wire W and wire ball W_B according to an example embodiment may each independently contain a conductive material. For example, the conductive material may include one or more selected from the group consisting of tungsten (W), aluminum (Al), copper (Cu), titanium (Ti), nickel (Ni), titanium nitride (TiN), tantalum (Ta), tantalum nitride (TaN), gold (Au) and silver (Ag).

The semiconductor package 10 according to the example embodiment may include the package board 20 placed on the bottom part of the first semiconductor chip 100. In other words, in the semiconductor package 10, the first semiconductor chip 100 may be placed on the package board 20.

The package board 20 according to the example embodiment may include a board 21, insulation layers, which are a first insulation layer 22 and a second insulation layer 23, and a wiring structure layer. The package board 20 may include the first insulation layer 22 disposed on an upper surface 20US of the package board 20 and the second insulation layer 23 disposed on a bottom surface 20BS of the package board 20. The wiring structure layer may include the upper part board pad 24 placed on the upper surface 20US of the package board 20, a bottom part board pad 25 placed on the bottom surface 20BS of the package board 20, and a wiring 26.

The board 21 according to the example embodiment may be, for example, but not particularly limited to, a printed circuit board (PCB) or a ceramic board. If the board 21 is a PCB, each of the board 21 and the insulating layers (e.g., the first insulation layer 22 and the second insulation layer 23) may include, for example, one or more selected from the group consisting of phenol resin, epoxy resin, and polyimide. For example, each of the board 21 and the insulating layers (e.g., the first insulation layer 22 and the second insulation layer 23) may include one or more selected from the group consisting of FR-4 material (reinforced epoxy resin), tetra-functional epoxy, polyphenylene ether, epoxy/polyphenylene oxide, bis-maleimidetriazine, cyanate ester, polyimide and liquid crystal polymer.

The surface of the board 21 according to the example embodiment is not particularly limited, but the surface may be covered by solder resist. In other words, each of the first insulation layer 22 disposed on the upper surface of the board 21 and the second insulation layer 23 disposed on the bottom surface of the board 21 may be a solder resist. Further, the board 21 may be single-layered in one example embodiment and multi-layered in another example embodiment.

The wiring structure layer according to the example embodiment may be placed inside each of the board 21 and the insulation layers which are the first insulation layer 22 and the second insulation layer 23. The upper part board pad 24 may be placed buried in the first insulation layer 22, and the bottom part board pad 25 may be placed buried in the second insulation layer 23. Further, the wiring 26 may electrically connect the upper part board pad 24 and the bottom part board pad 25, and may be placed inside the board 21. The wiring 26 may include a plurality of wiring patterns 26a and a plurality of vias 26b each providing connection between a corresponding pair of the wiring patterns 26a.

The number, spacing, arrangement and shape of the upper part board pad 24 and the bottom part board pad 25 according to the example embodiment are not limited to those illustrated and may change depending on the design.

Each of the upper part board pad 24, the bottom part board pad 25 and the wiring 26 according to the example embodiment may independently contain a conductive material. For example, the conductive material may include one or more selected from the group consisting of tungsten (W), aluminum (Al), copper (Cu), titanium (Ti), nickel (Ni), titanium nitride (TiN), tantalum (Ta), tantalum nitride (TaN), gold (Au) and silver (Ag).

The package board 20 according to the example embodiment may include an external connecting terminal 27 on the bottom surface 20BS. The external connecting terminal 27 may be attached to the bottom part board pad 25. The external connecting terminal 27 may be placed on the bottom part of the bottom part board pad 25. The external connecting terminal 27 may include a solder ball or a solder bump. The external connecting terminal 27 may be, for example, spherical or elliptical, but the external connecting terminal 27 is not limited thereto.

The external connecting terminal 27 according to the example embodiment is not limited, but may include, for example, one or more selected from the group consisting of tin (Sn), indium (In), bismuth (Bi), antimony (Sb), copper (Cu), silver (Ag), zinc (Zn) and lead (Pb). Meanwhile, the number, spacing, arrangement and shape of the external connecting terminal 27 are not limited to those illustrated and may change depending on the design.

The external connecting terminal 27 according to the example embodiment may electrically connect the wiring structure layer to an external device. Accordingly, the external connecting terminal 27 may provide an electrical signal to the wiring structure layer or provide an electrical signal (e.g., a power signal, a ground signal and/or an input/output signal) provided from the wiring structure layer to an external device.

The semiconductor package 10 according to the example embodiment may further include an adhesive layer 130 disposed between the package board 20 and the first semiconductor chip 100. Through the adhesive layer 130 placed between the upper surface 20US of the package board 20 and the bottom surface of the first semiconductor chip 100, the semiconductor package 10 may be fixed by bonding the first semiconductor chip 100 and the package board 20 to each other. Meanwhile, in an example embodiment, the adhesive layer 130 may be an insulating layer.

The adhesive layer 130 according to the example embodiment may include components of commonly used gluing agents or adhesives. The adhesive layer 130 is not particularly limited, but may include, for example, one or more selected from the group consisting of acrylic resin, vinyl acetate resin, ethylene-vinyl acetate copolymer, ethylene-acrylic acid ester copolymer, polyamide polyethylene polysulfone, epoxy resin, polyimide, polyamic acid, silicone phenolic rubber polymer, fluoro-rubber polymer and fluoro-resin. The adhesive layer 130 may be so-called DAF.

Meanwhile, the protection layer 120 and the adhesive layer 130 according to the example embodiment may include different materials. For example, the adhesive layer 130 may contain gluing agent or adhesive components, but the protection layer 120 may not include such components. The protection layer 120 and the adhesive layer 130 may both be insulating layers, but may include different materials, respectively.

The semiconductor package 10 according to the example embodiment may further include a molding film 30 that fills the opening 122 and covers the first semiconductor chip 100 and the second semiconductor chip 200. The molding film 30 may cover an upper surface 120US of the protection layer 120 exposed by the opening 122. The molding film 30 may include, for example, epoxy molding compound (EMC).

Meanwhile, the upper surface 120US of the protection layer 120 exposed by the opening 122 may be coplanar with the upper surface 121US of the bonding pad 121. Referring to FIG. 2, the upper surface 121US of the bonding pad 121 and the upper surface 120US of the protection layer 120 exposed by the opening 122 are located at the same level based on the direction (e.g., the z-axis direction) perpendicular to the upper surface 121US of the bonding pad 121, and this indicates that the upper surface 121US is coplanar with the upper surface 120US. The upper surface of the protection layer 120 includes at least one of a first surface portion coplanar with the upper surface of the bonding pad 121 or a portion inclined based on the upper surface 121US of the bonding pad 121.

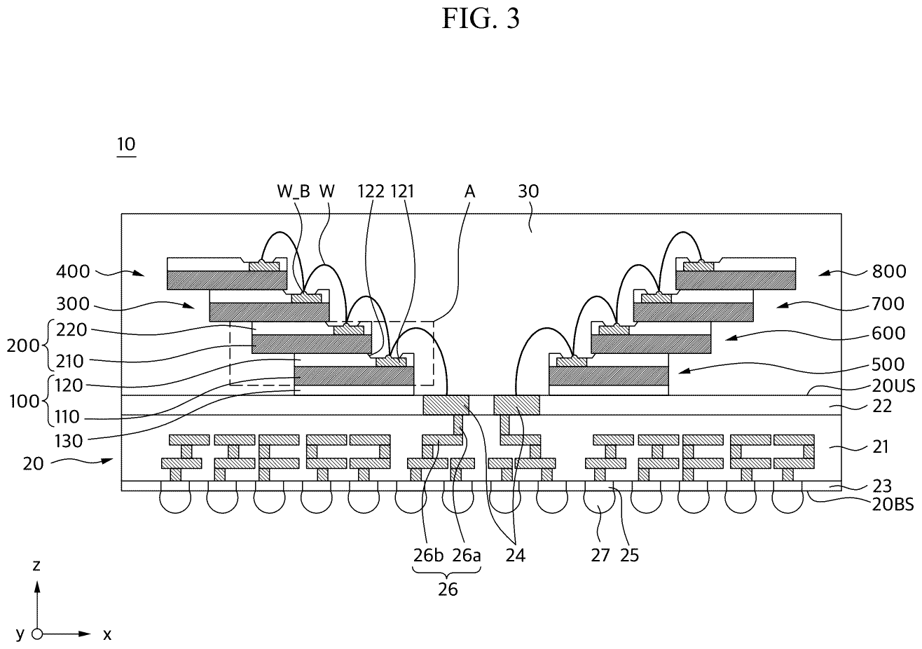

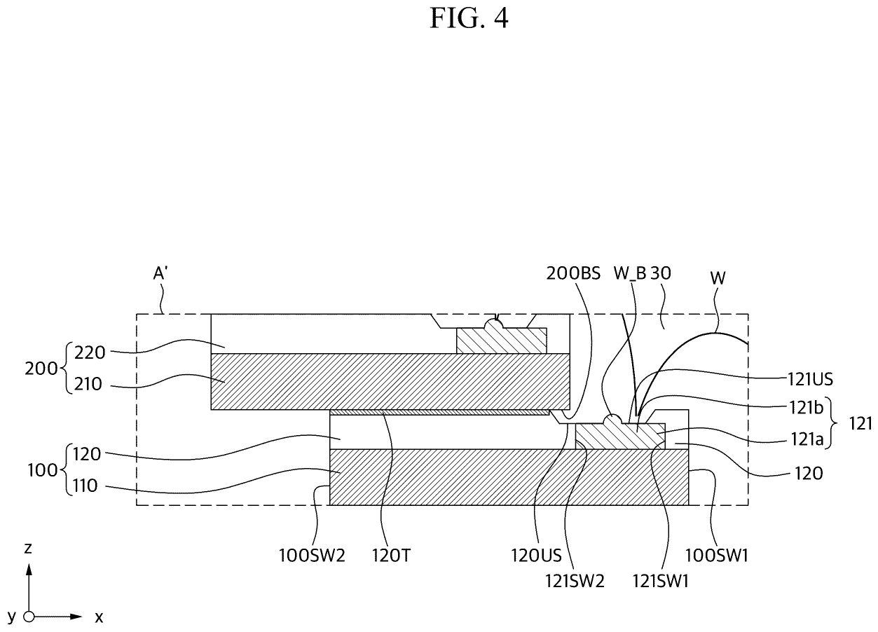

FIG. 3 is a plan view illustrating the semiconductor package 10 according to a second example embodiment. FIG. 4 is an enlarged plan view of portion A′ of FIG. 3. Hereinafter, contents different from the above descriptions with respect to FIGS. 1 and 2 are described, and reference may be made to the foregoing unless contradictory.

When compared to the semiconductor package 10 according to the first embodiment, FIG. 3 illustrates that in the semiconductor package 10 according to the second example embodiment, the second semiconductor chip 200 stacked on the first semiconductor chip 100 is moved in the width direction (the x-axis direction) of the first semiconductor chip 100. In other words, the second semiconductor chip 200 according to the example embodiment may overlap the opening 122 of the first semiconductor chip 100 and may not overlap the bonding pad 121 when viewed from the direction perpendicular to the upper surface 121US of the bonding pad 121 of the first semiconductor chip 100 (the z-axis direction). The second semiconductor chip 200 may partially overlap the opening 122 of the first semiconductor chip 100, and at the same time, may not overlap with the bonding pad 121 when viewed from the direction perpendicular to the upper surface 121US of the bonding pad 121 of the first semiconductor chip 100 (the z-axis direction).

Further, when viewed from the direction perpendicular to the upper surface 121US of the bonding pad 121 of the first semiconductor chip 100 (the z-axis direction), the bottom surface 200BS of the second semiconductor chip 200 that overlaps the opening 122 may overlap the upper surface 120US of the protection layer 120 that is exposed by the opening 122.

As described above, in the semiconductor package 10 according to the example embodiment, no adhesive layer is disposed between the first semiconductor chip 100 and the second semiconductor chip 200, and thus the adhesion between the two semiconductor chips may be reduced compared to the adhesion with an adhesive layer. Therefore, the second semiconductor chip 200 stacked on the first semiconductor chip 100 may be slidably moved along the first semiconductor chip 100. For example, the second semiconductor chip 200 may be slidably moved in the +x-axis direction along the protection layer 120 of the first semiconductor chip 100.

The protection layer 120 according to the example embodiment may include the surface treatment layer 120T that contacts the bottom surface 200BS of the second semiconductor chip 200. The surface treatment layer 120T may have adhesive properties through surface treatment. According thereto, with the minimal fixed effect (e.g., with an effect of such adhesive properties) of the first semiconductor chip 100 on the second semiconductor chip 200, the second semiconductor chip 200 may be mitigated or prevented from sliding even by a slight external force.

According to the example embodiment, when viewed from the direction perpendicular to the upper surface 121US of the bonding pad 121 of the first semiconductor chip 100 (the z-axis direction), because the upper surface 121US of the second part 121b of the bonding pad 121 is exposed from the protection layer 120 through the opening 122, the second semiconductor chip 200 can be moved according to the width direction (x-axis direction) of the first semiconductor chip 100 in order not to overlap the bonding pad 121. In other words, the second semiconductor chip 200 may not move according to the width direction (the x-axis direction) of the first semiconductor chip 100 until the second semiconductor chip 200 overlaps the bonding pad 121 when viewed from the direction perpendicular to the upper surface 121US of the bonding pad 121 of the first semiconductor chip 100 (the z-axis direction), and the protection layer 120 may function as a kind of movement stop layer.

According to the example embodiment, when viewed from the direction perpendicular to the upper surface 121US of the bonding pad 121 of the first semiconductor chip 100 (the z-axis direction), the wire ball W_B may be spaced apart from the second semiconductor chip 200 because the second semiconductor chip 200 does not overlap the bonding pad 121 even though the second semiconductor chip 200 overlaps the opening 122.

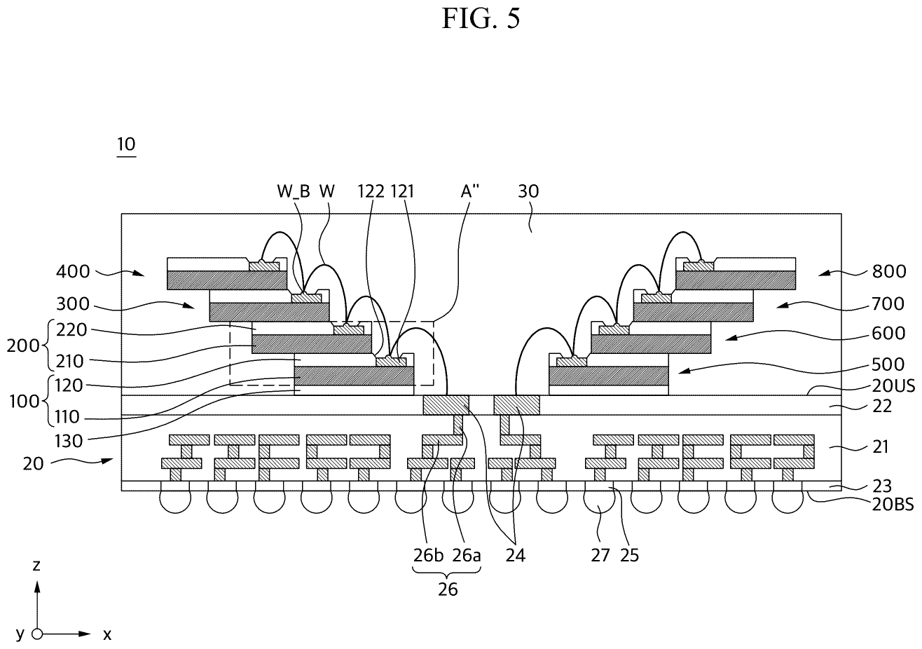

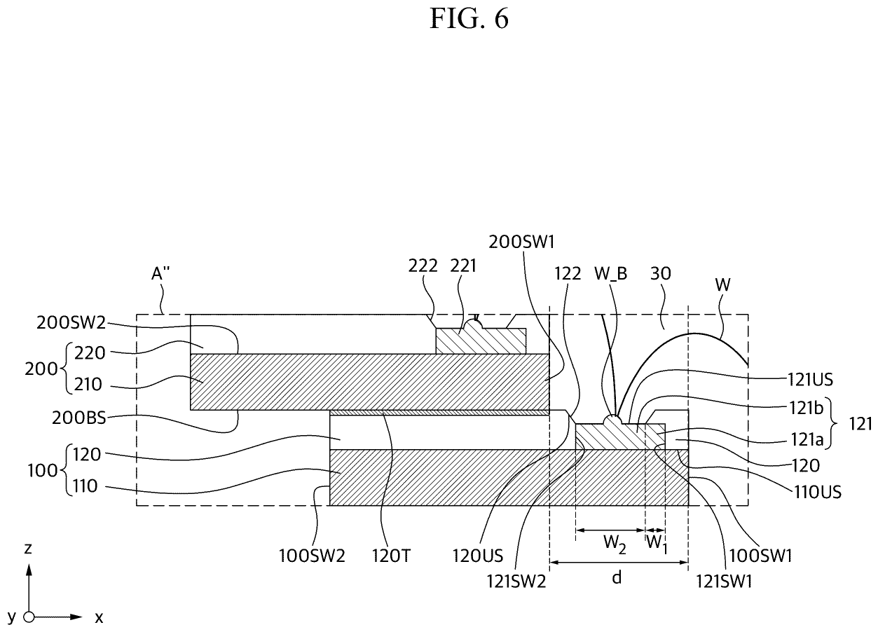

FIG. 5 is a plan view illustrating the semiconductor package 10 according to a third example embodiment. FIG. 6 is an enlarged plan view of portion A″ of FIG. 5. Hereinafter, contents different from the above descriptions with respect to FIGS. 1 to 4 are described, and reference may be made to the foregoing unless contradictory.

In the semiconductor package 10 according to the example embodiment, the upper surface 120US of the protection layer 120 exposed through the opening 122 may include an inclined surface based on the upper surface 121US of the bonding pad 121. Referring to FIG. 6, in the example embodiment, the upper surface 120US of the protection layer 120 may have an inclined portion along the distance direction (the y-axis direction) between the second pad side wall 121SW2 of the first bonding pad 121 and the first semiconductor chip 100. In another example embodiment, the upper surface of the opening 122 of the protection layer 120 includes an inclined portion along the distance direction (the y-axis direction) between the second pad side wall 121SW2 of the first bonding pad 121 and the first semiconductor chip 100. The inclined portion may be in contact along the distance direction (the y-axis direction) between the second pad side wall 121SW2 of the first bonding pad 121 and the first semiconductor chip 100.

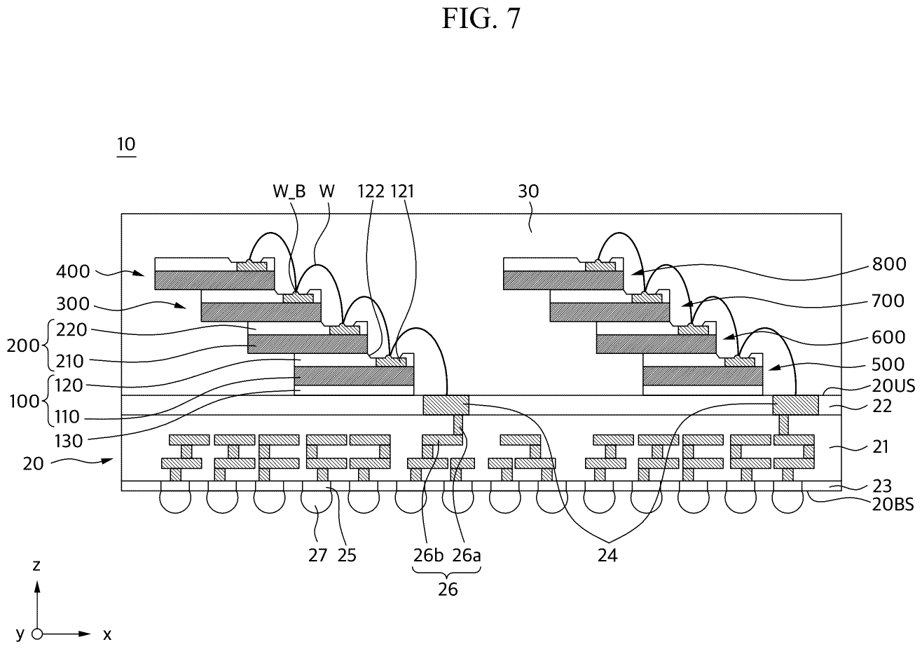

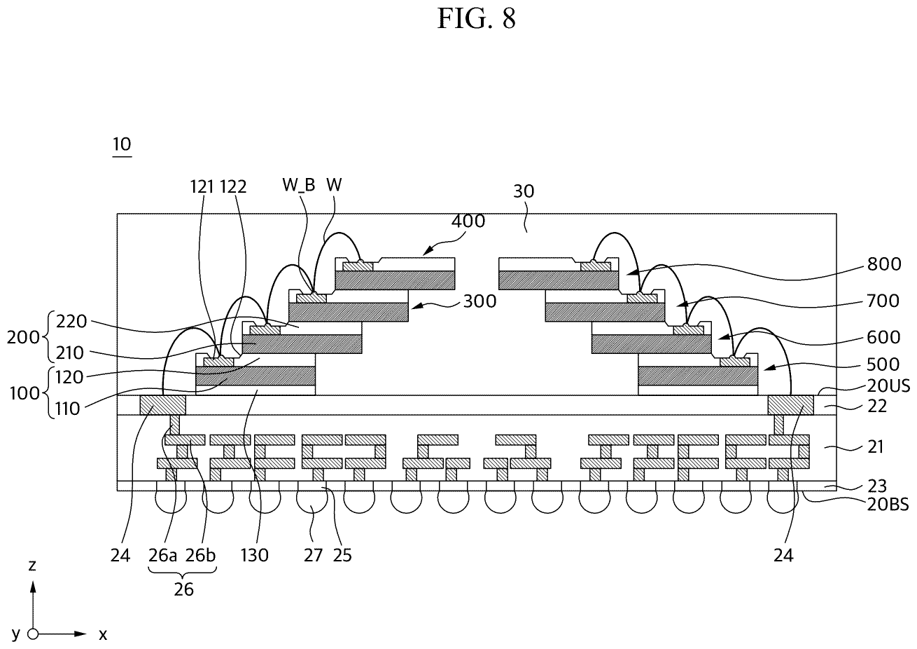

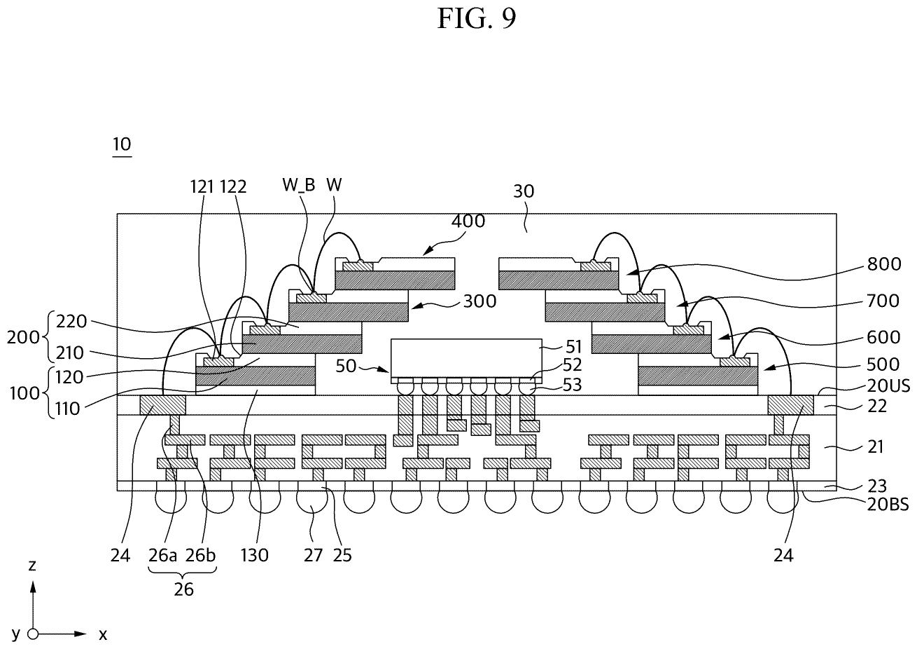

FIG. 7 is a plan view illustrating the semiconductor package 10 according to a fourth example embodiment. FIG. 8 is a plan view illustrating the semiconductor package 10 according to a fifth example embodiment. FIG. 9 is a plan view illustrating the semiconductor package 10 according to a sixth example embodiment.

In the semiconductor package 10 according to the example embodiment, the way semiconductor chips are stacked is not particularly limited. In an example embodiment, the first semiconductor chip 100, the second semiconductor chip 200, the third semiconductor chip 300, and the fourth semiconductor chip 400 may be sequentially stacked by shifting a desired (or alternatively, predetermined) distance in the first direction. Referring to FIGS. 1 and 3, a direction (e.g., the −x direction), in which the first semiconductor chip 100 to the fourth semiconductor chip 400 are shifted and a direction (e.g., the +x direction) in which the fifth semiconductor chip 500 to the eighth semiconductor chip 800 are shifted may be opposite to each other. Referring to FIG. 7, a direction (e.g., the −x direction) in which the first semiconductor chip 100 to the fourth semiconductor chip 400 are shifted and a direction (e.g., the −x direction) in which the fifth semiconductor chip 500 to the eighth semiconductor chip 800 are shifted may be the same direction. Referring to FIG. 8, a direction (e.g., the +x direction) in which the first semiconductor chip 100 to the fourth semiconductor chip 400 are shifted and a direction (e.g., the −x direction) in which the fifth semiconductor chip 500 to the eighth semiconductor chip 800 are shifted may be opposite directions. In other words, the semiconductor chips may be stacked in a different way from what is illustrated in FIGS. 1 and 3.

Referring to FIG. 9, the semiconductor package 10 according to the example embodiment may further include a controller chip 50 disposed on the package board 20. The controller chip 50 may include a controller chip board 51. The controller chip board 51 may be made of or include the same material as the first semiconductor board 110. The controller chip 50 may include a plurality of controller pads 52 disposed on the bottom surface thereof. The controller chip 50 may be arranged so that the plurality of controller pads 52 located on the bottom surface of the controller chip 50 face the upper surface 20US of the package board 20. A plurality of controller connecting terminals 53 may be attached to the plurality of controller pads 52. The controller connecting terminals 53 may be solder balls or solder bumps.

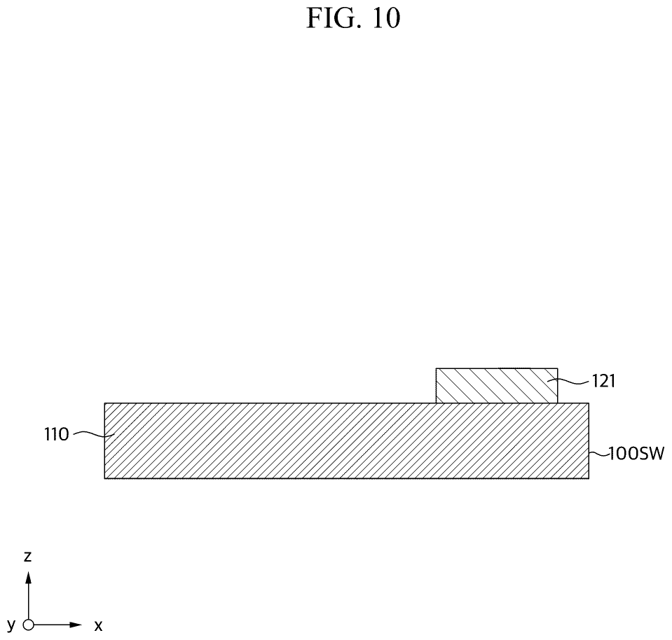

FIGS. 10 to 26 are cross-sectional views illustrating a manufacturing method of the semiconductor package 10 operation by operation according to an example embodiment.

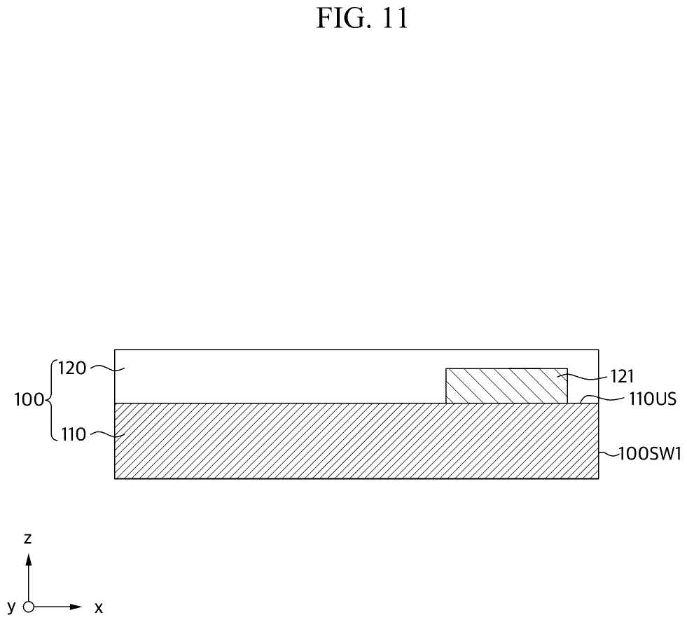

Referring to FIG. 10, the method of manufacturing the semiconductor package 10 may include forming the bonding pad 121 on the first semiconductor board 110 on one side of which semiconductor devices (not illustrated) are formed. For example, by forming a metal layer on one side of the first semiconductor board 110 on which the semiconductor devices are formed and then patterning the metal layer, the bonding pad 121 may be formed adjacent to one side wall of the first semiconductor board 110 based on the x-axis direction. The one side wall of the first semiconductor board 110 may later become the first side wall 100SW1 of the first semiconductor chip 100 (see FIG. 11). Further, in an example embodiment, a test pad (not illustrated) may be formed on a side opposite to the side where the bonding pad 121 is formed based on the x-axis direction through the above-described patterning. The test pads may be used for functional testing.

Referring to FIG. 11, the method of manufacturing the semiconductor package 10 may include forming the protection layer 120 covering the bonding pad 121. The protection layer 120 may be formed to cover all exposed portions of the bonding pad 121 in FIG. 10.

Referring to FIGS. 11 to 13, the method of manufacturing the semiconductor package 10 may include patterning the protection layer 120 to form the opening 122 in order to partially expose the bonding pad 121 when viewed in the z-axis direction.

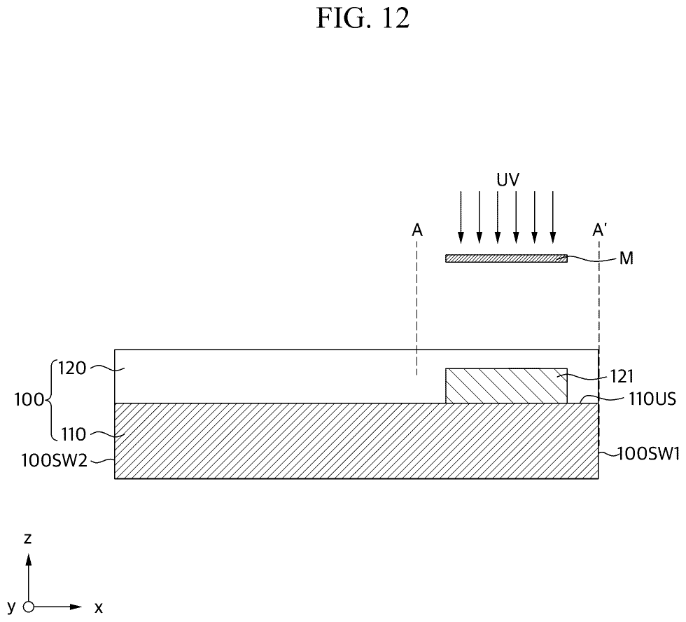

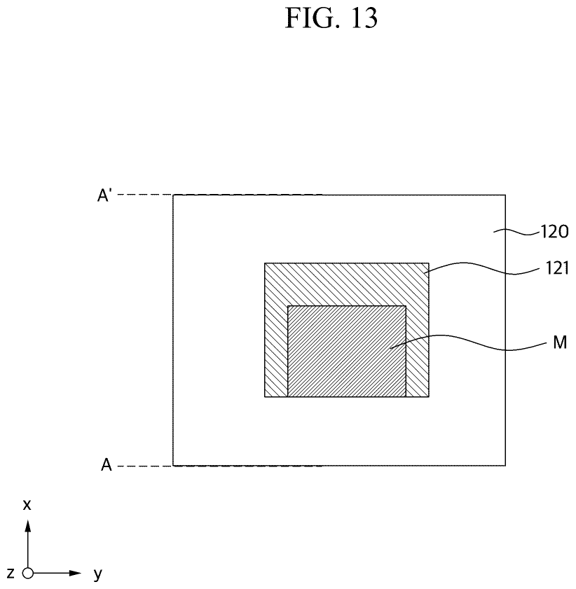

Referring to FIGS. 12 and 13, the method of manufacturing the semiconductor package 10 may include positioning a mask M to be perpendicular to the bonding pad 121 (which is the +z-axis direction), and positioning the mask M biased toward one side (which is the −x-axis direction) so that the bonding pad 121 can be separated into the first part 121a and the second part 121b.

Referring to FIG. 13, it is illustrated that the mask (M) is positioned biased in the −x-axis direction based on the bonding pad 121. The mask M may be positioned to overlap all of the bonding pads 121 when viewed in the z-axis direction. The overlapping portion may later be the opening 122.

In another example embodiment, the mask M may be located more biased toward the −x-axis direction, and thus may include a first portion that partially overlaps the bonding pad 121 when viewed in the z-axis direction and the remaining portion that does not overlap when viewed in the z-axis direction. In other words, the protection layer 120 may include a region that does not cover the bonding pad 121. In this case, however, the first portion overlapping the bonding pad 121 should an area sufficient to allow the wire ball W_B for the wire W to contact the bonding pad 121 in the later process.

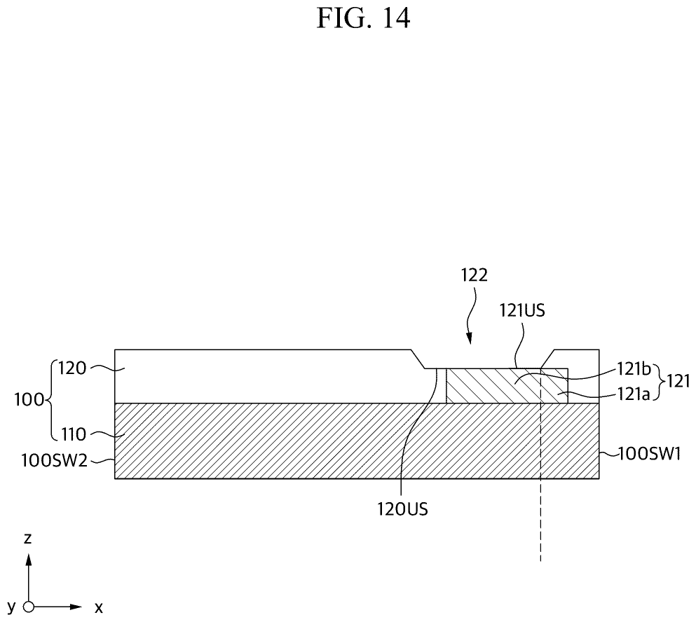

Referring to FIG. 14, by adjusting the position of the mask M, the opening 122 that partially exposes the upper surface 121US of the bonding pad 121 may be formed. Further, by adjusting the position of the mask M, the bonding pad 121 may be divided to the first part 121a where the upper surface 121US of the bonding pad 121 overlaps the protection layer 120 when viewed in the z-axis direction and the second part 121b where the upper surface 121US of the bonding pad 121 is exposed from the protection layer 120 through the opening 122.

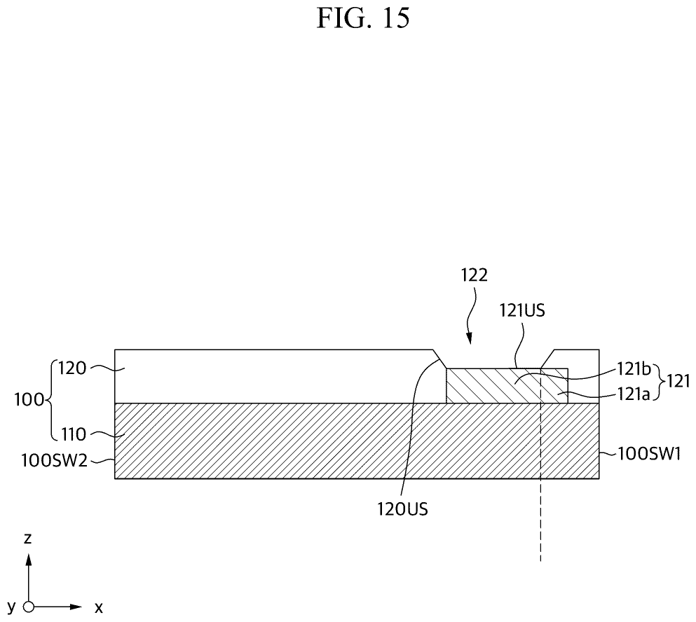

Referring to FIG. 14, by adjusting the position of the mask M, the upper surface 120US of the protection layer 120 exposed by the opening 122 may be disposed to be coplanar with the upper surface 121US of the bonding pad 121 based on the direction perpendicular to the upper surface 121US of the bonding pad 121 (the z-axis direction). Meanwhile, referring to FIG. 15, with adjustment on the position of the mask M, the upper surface 120US of the protection layer 120 exposed through the opening 122 may include an inclined surface based on the upper surface 121US of the bonding pad 121. Further, referring to FIGS. 6 and 15, with adjustment on the position of the mask M, the inclined surface included in the upper surface 120US of the protection layer 120 may contact the second pad side wall 121SW2 of the first bonding pad 121 along the distance direction (the y-axis direction) of the first semiconductor chip 100.

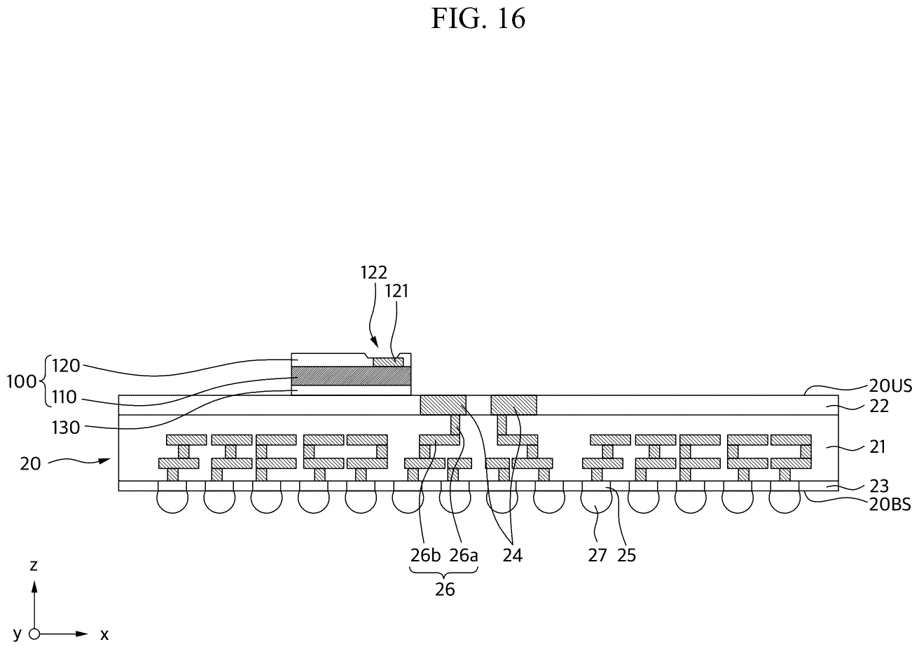

Referring to FIG. 16, the method of manufacturing the semiconductor package 10 may include manufacturing the first semiconductor chip 100 through the series of operations described above and attaching the first semiconductor chip 100 manufactured on the package board 20. The package board 20 and the first semiconductor chip 100 can be bonded to each other by the adhesive layer 130. In an example embodiment, the package board 20 may have the adhesive layer 130 pre-placed at a location where the first semiconductor chip 100 is to be adhered, and the first semiconductor chip 100 may be adhered on the adhesive layer 130. Here, the surface where the first semiconductor chip 100 contacts the adhesive layer 130 is the opposite surface of the surface on which the semiconductor devices are formed. In another example embodiment, in the first semiconductor chip 100, the adhesive layer 130 may be attached in advance to the surface opposite to the surface on which the semiconductor devices are formed and then adhered to the package board 20.

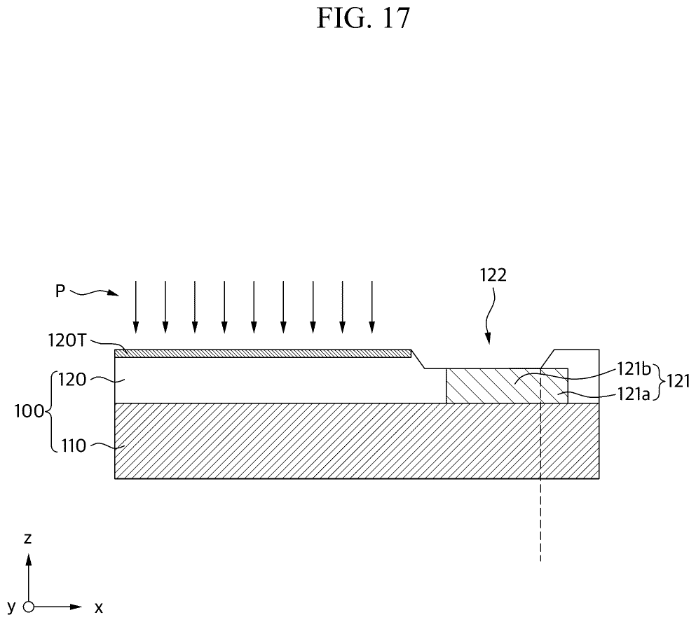

Referring to FIG. 17, the method of manufacturing the semiconductor package 10 may include a surface treatment on a portion of the protection layer 120 of the first semiconductor chip 100 to form the surface treatment layer 120T. In the surface treatment, plasma P or low-wavelength energy rays may be used, for example.

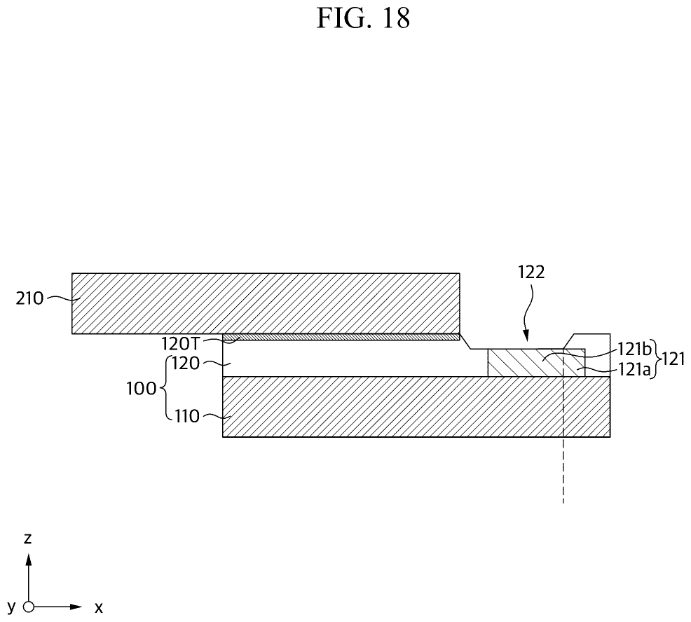

Referring to FIG. 18, the method of manufacturing the semiconductor package 10 may include stacking the second semiconductor chip 200 on the surface treatment layer 120T. FIG. 18 illustrates the second semiconductor chip 200 in which the second semiconductor board 210 is excluded. Here, based on the x-axis direction, the separated distance d between the first side wall 100SW1 of the first semiconductor chip 100 and the third side wall 200SW1 of the second semiconductor chip 200 may be at least 20 μm or greater. In another example embodiment, separated distance d between the first side wall 100SW1 and the third side wall 200SW1 based on the x-axis direction may be, for example, 100 μm or greater or 200 μm or less. However, the separated distance d is not limited thereto.

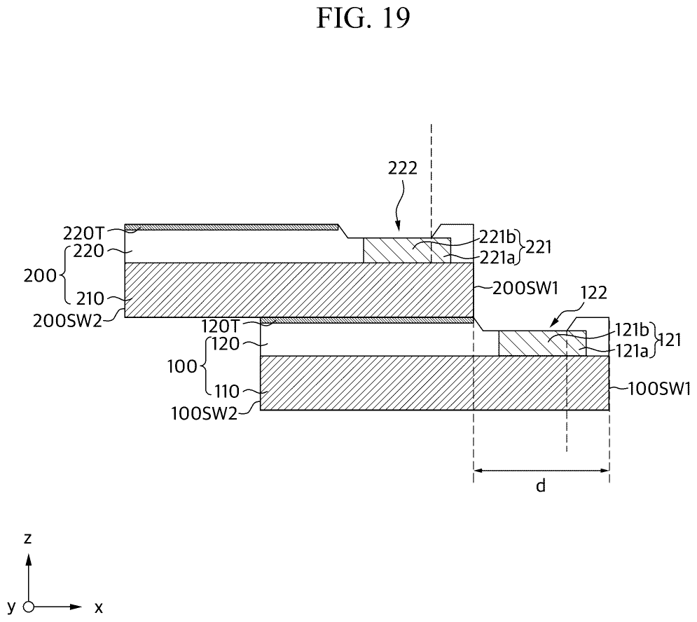

Referring to FIG. 19, the method of manufacturing the semiconductor package 10 may include manufacturing the second semiconductor chip 200 including the bonding pad 221 where the upper surface is partially exposed through an opening 222 and includes a first part 221a and a second part 221b, and a surface treatment layer 200T, by repeating the above-described operations.

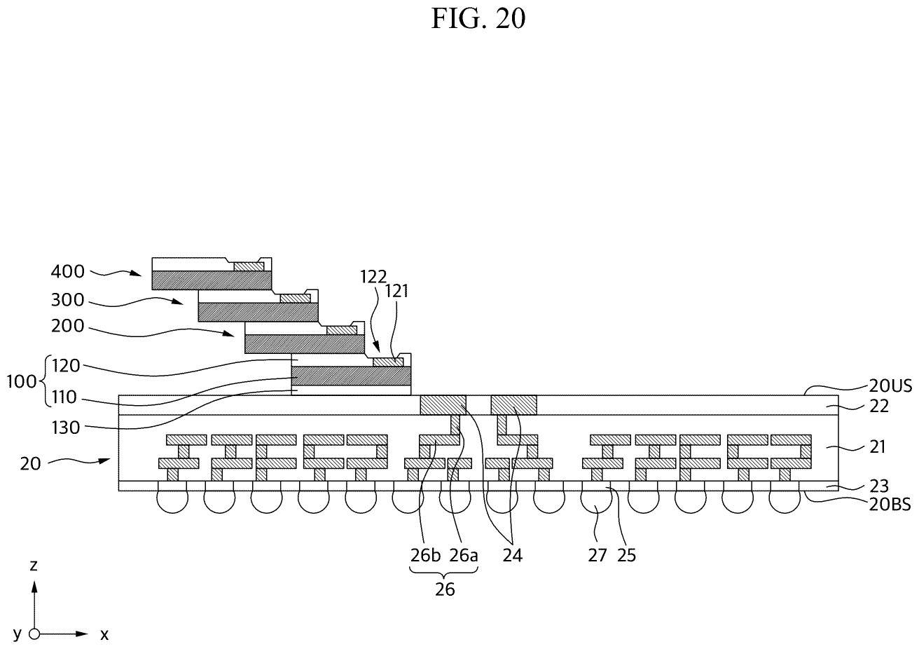

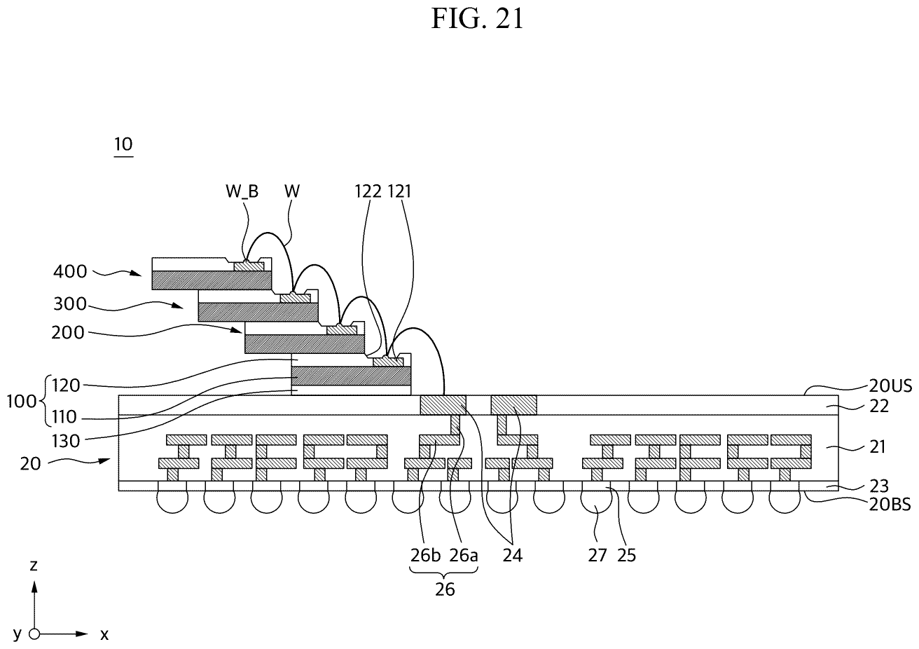

Referring to FIG. 20, by repeating the above-described operations, the third semiconductor chip 300 and the fourth semiconductor chip 400 may also be stacked in the same manner. Referring to FIG. 21, the method of manufacturing the semiconductor package 10 may include electrically connecting the first semiconductor chip 100 to the fourth semiconductor chip 400 with the wire W, and electrically connecting the first semiconductor chip 100 to the fourth semiconductor chip 400 with the package board 20, or electrically connecting each of the first semiconductor chip 100 to the fourth semiconductor chip 400 individually with the package board 20. For example, the wire W may electrically connect the upper part board pad 24 and the bonding pad of each of the first semiconductor chip 100, the second semiconductor chip 200, the third semiconductor chip 300 and the fourth semiconductor chip 400. Further, connecting according to a stacked order may be carried out by the wire W.

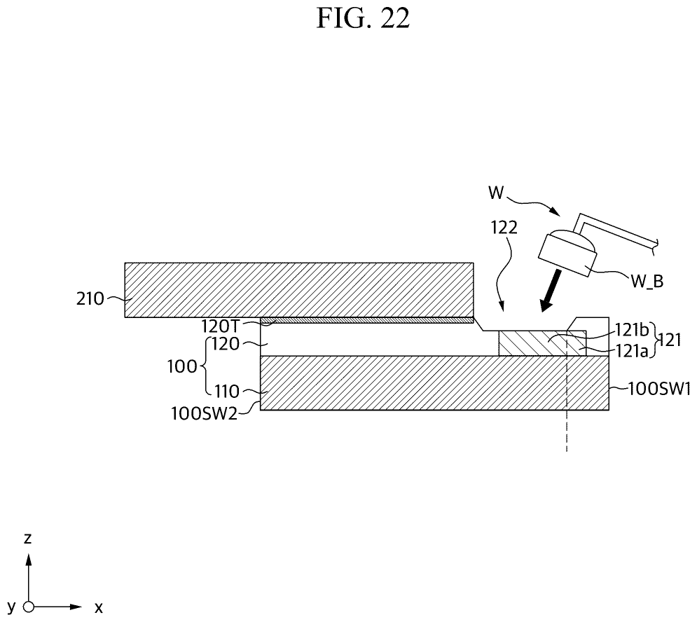

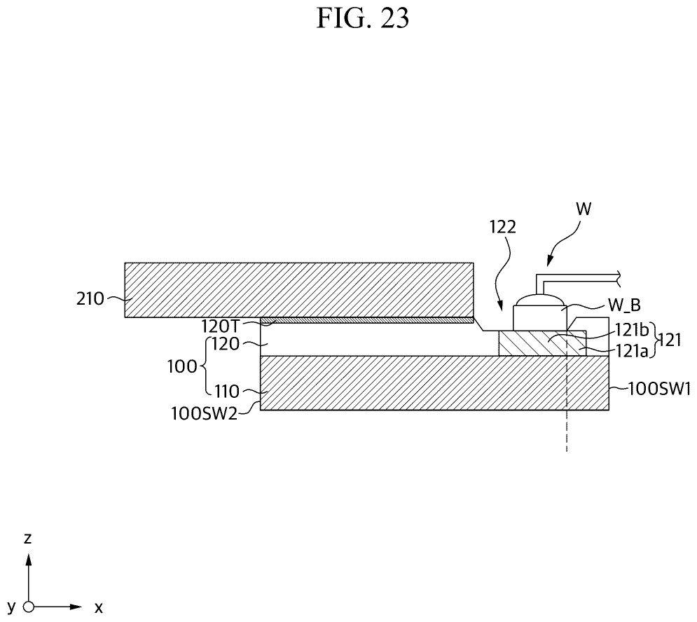

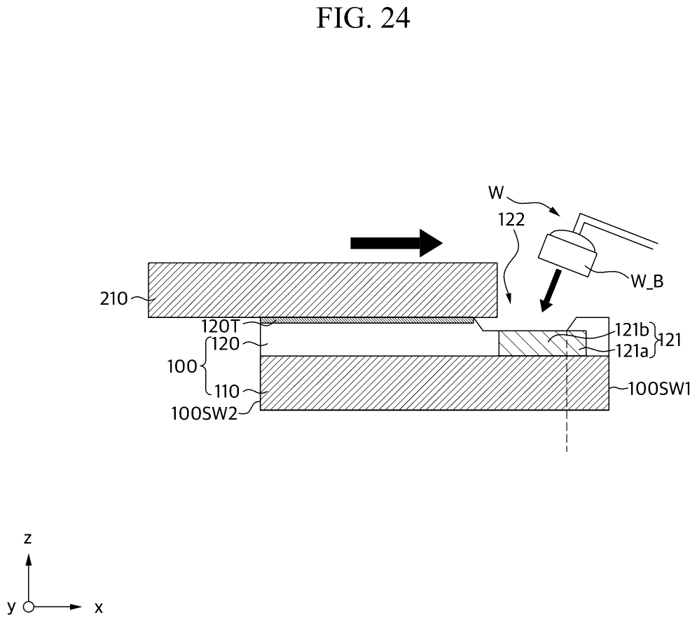

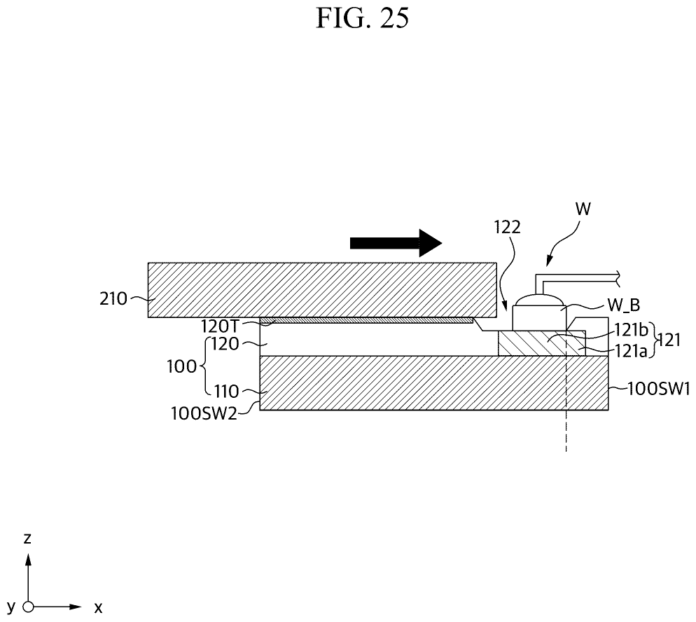

Referring to FIGS. 22 and 23, the wire ball W_B may contact the second part 121b partially exposed through the opening 122, and the wire ball W_B may be separated from the second semiconductor chip 200. Referring to FIGS. 24 and 25, even if the second semiconductor chip 200 is moved in one direction (the +x direction) where the bonding pad 121 is placed, the wire ball W_B may contact the second part 121b partially exposed through the opening 122, and the wire ball W_B may be separated from the second semiconductor chip 200.

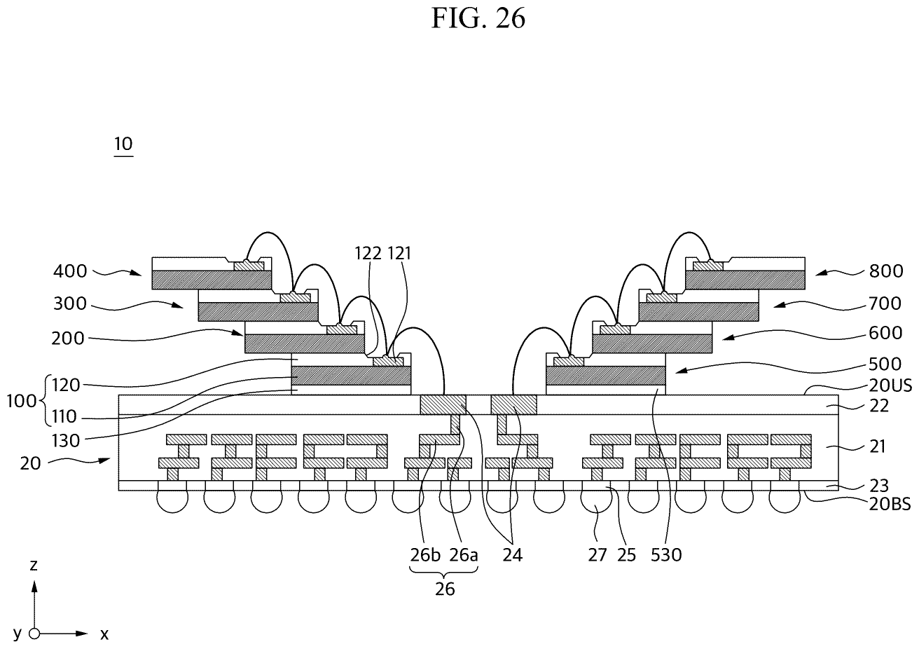

Referring to FIG. 26, the fifth semiconductor chip 500, the sixth semiconductor chip 600, the seventh semiconductor chip 700, and the eight semiconductor chip 800 may also be stacked by repeating the above operations. The method of manufacturing the semiconductor package 10 is not limited to FIG. 26. In some example embodiments, the fifth semiconductor chip 500 to the eight semiconductor chip 800 may be differently stacked as illustrated in FIGS. 3, 7, and 8.

The method of manufacturing the semiconductor package 10 according to an example embodiment includes forming the molding film 30, and the molding film 30 may be formed to surround or cover all elements placed on the package board 20. By forming the molding film 30, the semiconductor package 10 as illustrated in FIG. 1 may be manufactured.

The example embodiments of the present disclosure are described with reference to the attached drawings. However, the present disclosure is not limited to the example embodiments described above, and the present disclosure can be manufactured in various other forms, and a person skilled in the art to which the present disclosure pertains will understand that the present disclosure can be implemented in other specific forms without changing the technical ideas or essential features of the present disclosure. Therefore, the example embodiments described above should be understood in all respects as illustrative and not limiting.

What is claimed is:

1. A semiconductor package comprising:
a first semiconductor chip including a first semiconductor board, a bonding pad on the first semiconductor board, and a protection layer covering an upper surface of the first semiconductor board, the protection layer including a recessed portion, the recessed portion exposing at least a portion of an upper surface of the bonding pad therethrough;
a second semiconductor chip including a second semiconductor board, the second semiconductor board being in direct contact with the protection layer; and
a wire electrically connecting the first semiconductor chip and the second semiconductor chip, the wire being connected to the bonding pad.

2. The semiconductor package of claim 1, further comprising:
a package board on a bottom part of the first semiconductor chip; and
an adhesive layer between the package board and the first semiconductor chip.

3. The semiconductor package of claim 2, wherein the adhesive layer and the protection layer each contain different materials.

4. The semiconductor package of claim 1, wherein the bonding pad comprises:
a first part where the upper surface of the bonding pad overlaps the protection layer when viewed in a first direction perpendicular to the upper surface of the boding pad; and
a second part where the upper surface of the bonding pad is exposed through the protection layer when viewed in the first direction.

5. The semiconductor package of claim 4, wherein the first semiconductor chip comprises:
a first side wall not overlapping the second semiconductor chip when viewed in the first direction; and
a second side wall being on an opposite side of the first side wall based on a width direction of the first semiconductor chip, the second side wall overlapping the second semiconductor chip when viewed in the first direction,
wherein the first part is closer to the first side wall than the second part based on the width direction of the first semiconductor chip.

6. The semiconductor package of claim 4, wherein a width of the second part is greater than a width of the first part based on the width direction of the first semiconductor chip.

7. The semiconductor package of claim 1, wherein the protection layer comprises a surface treatment layer in contact with a bottom surface of the second semiconductor chip.

8. The semiconductor package of claim 7, wherein the surface treatment layer is a portion of the protection layer treated by plasma or low-wavelength energy rays.

9. The semiconductor package of claim 5, wherein the second semiconductor chip comprises:
a third side wall overlapping the first semiconductor chip when viewed in the first direction; and
a fourth side wall on an opposite side to the third side wall based on the width direction of the first semiconductor chip the fourth side wall not overlapping the first semiconductor chip when viewed in the first direction,
wherein the first side wall and the third side wall have a separation distance of 20 μm or greater based on the width direction of the first semiconductor chip.

10. The semiconductor package of claim 1, further comprising:
wire balls on the bonding pad and electrically connecting the wire and the bonding pad,
wherein the wire balls are spaced from the second semiconductor chip.

11. The semiconductor package of claim 1, further comprising:
a molding film covering an upper surface the recessed portion and the first semiconductor chip and the second semiconductor chip.

12. The semiconductor package of claim 11, wherein the upper surface of the recessed portion of the protection layer includes at least one of a first surface portion coplanar with the upper surface of the bonding pad or a portion inclined based on the upper surface of the bonding pad.

13. The semiconductor package of claim 1, wherein the second semiconductor chip does not overlap the recessed portion when viewed in a first direction perpendicular to the upper surface of the bonding pad.

14. The semiconductor package of claim 1, wherein the second semiconductor chip overlaps the recessed portion and does not overlap the bonding pad when viewed in a first direction perpendicular to the upper surface of the bonding pad.

15. The semiconductor package of claim 14, wherein a bottom surface of the second semiconductor chip overlapping the recessed portion when viewed in the first direction and overlaps the upper surface of the protection layer exposed in the recessed portion.

16. A semiconductor package comprising:
a first semiconductor chip including a first semiconductor board, a bonding pad on the first semiconductor board, and a protection layer covering an upper surface of the first semiconductor board, the protection layer including a recessed portion, the recessed portion exposing at least a portion of an upper surface of the bonding pad therethrough;
a second semiconductor chip including a second semiconductor board, the second semiconductor board being in direct contact with the protection layer; and
a wire electrically connecting the first semiconductor chip and the second semiconductor chip, the wire being connected to the bonding pad,
wherein the bonding pad comprises
a first pad side wall overlapping the protection layer when viewed in a first direction perpendicular to the upper surface of the bonding pad, and
a second pad side wall being on an opposite side of the first pad side wall based on a width direction of the first semiconductor chip, the second pad side wall not overlapping the protection layer when viewed in the first direction.

17. The semiconductor package of claim 16, wherein the first semiconductor chip comprises:
a first side wall not overlapping the second semiconductor chip in the first direction; and
a second side wall being on an opposite side of the first side wall based on the width direction of the first semiconductor chip, the second side wall overlapping the second semiconductor chip in the first direction,
wherein the first pad side wall is closer to the first side wall than the second pad side wall based on the width direction of the first semiconductor chip.

18. The semiconductor package of claim 16, wherein the bonding pad comprises:
a first part where the upper surface of the bonding pad overlaps the protection layer when viewed in the first direction, the first part including the first pad side wall; and
a second part where the upper surface of the bonding pad is exposed through the protection layer when viewed in the first direction, the second part including the second pad side wall,
wherein a width of the second part is greater than a width of the first part based on the width direction of the first semiconductor chip.

19. The semiconductor package of claim 16, wherein the protection layer comprises a surface treatment layer in contact with a bottom surface of the second semiconductor chip.

20. A semiconductor package comprising:
a package board;
a first semiconductor chip on the package board, the first semiconductor chip including a first semiconductor board, a bonding pad on the first semiconductor board, and a protection layer covering an upper surface of the first semiconductor board, the protection layer including an recessed portion, the recessed portion exposing at least a portion of an upper surface of the bonding pad therethrough;
an adhesive layer between the package board and the first semiconductor chip;
a second semiconductor chip comprising a second semiconductor board, the second semiconductor chip being in direct contact with the protection layer;
a wire electrically connecting the first semiconductor chip and the second semiconductor chip, the wire being connected with the bonding pad;
a wire ball on the bonding pad, the wire ball connecting the wire and the bonding pad; and
a molding film covering the recessed portion, the first semiconductor chip, and the second semiconductor chip,
wherein the first semiconductor chip comprises
a first side wall not overlapping the second semiconductor chip when viewed in a first direction perpendicular to the upper surface of the bonding pad, and
a second side wall being on an opposite side of the first side wall based on a width direction of the first semiconductor chip, the second side wall overlapping the second semiconductor chip when viewed in the first direction,
wherein the bonding pad comprises
a first part where the upper surface of the bonding pad overlaps the protection layer when viewed in the first direction, and
a second part where the upper surface of the bonding pad is exposed through the protection layer when viewed in the first direction, and
wherein the first part is closer to the first side wall than the second part based on the width direction of the first semiconductor chip.
